(19) United States
(12) Patent Application Publication
(10) Pub. No.: US 2017/0069520 A1
(43) Pub. Date: Mar. 9, 2017

(54) JOINED STRUCTURE

(71) Applicant: NGK INSULATORS, LTD., Nagoya-City (JP)

(72) Inventor: Yutaka UNNO, Handa-City (JP)

(73) Assignee: NGK INSULATORS, LTD., Nagoya-City (JP)

(21) Appl. No.: 15/353,954

(22) Filed: Nov. 17, 2016

Related U.S. Application Data
(63) Continuation of application No. PCT/JP2015/067038, filed on Jun. 12, 2015.

(30) Foreign Application Priority Data
Jun. 27, 2014 (JP) 2014-132305

(51) Int. Cl. H01L 21/683; H01L 21/67; H05B 3/28

(52) U.S. Cl. CPC H01L 21/6833; H05B 3/28; H01L 21/67103

(57) ABSTRACT

A ceramic heater 10 includes a ceramic member 12, a heater element 14, a connection member 16, and an externally conducting member 18. The connection member 16 is a cylindrical metal member embedded in a bottom surface of a hole 12c in the ceramic member 12 so as to reach the heater element 14. The connection member 16 has a diameter D of 3.5 to 5 mm. The connection member 16 includes a circular surface that touches the heater element 14, a cylinder side surface, and a corner portion 16b between the circular surface and the cylinder side surface. The corner portion 16b has a curvature radius R of 0.3 to 1.5 mm. The ratio R/D is within a range of 0.09 to 0.30. The externally conducting member 18 is joined to the connection member 16 with a joining layer 20 interposed therebetween.

### BACKGROUND OF THE INVENTION

1. Field of the Invention

The present invention relates to a joined structure.

2. Description of the Related Art

Known examples of a joined structure in which a ceramic member and a metal member are joined to each other include a structure described in PTL 1. PTL 1 discloses a ceramic heater 210 illustrated in FIG. 5 as an example of such a joined structure. The ceramic heater 210 includes a ceramic member 212, a connection member 216, an externally conducting member 218, and a guide member 222. The ceramic member 212 is a disk-shaped member having a heater element 214 embedded therein. The connection member 216 is a cylindrical metal member embedded in the bottom surface of a cylindrical closed-end hole 212c of the ceramic member 212 so as to reach the heater element 214. The externally conducting member 218 is a metal member joined to the surface of the connection member 216 exposed from the bottom surface of the hole 212c with a joining layer 220 interposed therebetween. The externally conducting member 218 is used for feeding power to the heater element 214. The guide member 222 is a cylinder member that surrounds part of the outer peripheral surface of the externally conducting member 218, the part being located near the connection member. An end surface of the guide member 222 facing a flange of the externally conducting member 218 is joined to the flange with a joining layer 224 interposed therebetween and an end surface of the guide member 222 facing the bottom surface of the hole 212c is joined to the externally conducting member 218 and the connection member 216 with a joining layer 220 interposed therebetween. Part of the outer peripheral surface of the externally conducting member 218, the part being located near the connection member, is insulated with the guide member 222 from the oxidizing atmosphere. The ceramic heater 210 is described that the joint strength between the connection member 216 and the externally conducting member 218 is high.

### CITATION LIST

### Patent Literature

PTL 1: Japanese Patent No. 3790000

### SUMMARY OF THE INVENTION

In recent years, devices having higher joint strength than the above-described ceramic heater 210 have been desired. An increase of the diameter of the connection member 216 is a conceivable way to enhance the joint strength further. The increase of the diameter, however, encourages development of cracks in the ceramic member 212. Specifically, when the ceramic heater 210 is used at a high temperature, thermal stress is concentrated on corner portions of the surface of the connection member 216 at which the connection member 216 comes into contact with the heater element 214. When the connection member 216 has a larger diameter, thermal stress increases, whereby cracks may develop in the ceramic member 212 from the corner portions and the ceramic member 212 may be broken. Also in a ceramic manufacturing process such as firing or joining, when the connection member 216 has a larger diameter, thermal stress increases, whereby cracks may develop in the ceramic member 212 from the corner portions of the connection member 216.

The invention was made to solve the above-described problem and a main object of the invention is to reduce the risk of breakage of a ceramic member in a joined structure while the joint strength of the joined structure is further enhanced.

A first joined structure of the present invention comprises:

a ceramic member including a wafer-placement surface;

an embedded electrode embedded in the ceramic member and having a shape along a shape of the wafer-placement surface;

a connection member made of a metal and embedded in a surface of the ceramic member opposite to the wafer-placement surface so as to reach the embedded electrode; and

an externally conducting member made of a metal and joined to a surface of the connection member exposed to an outside with a joining layer interposed therebetween,

wherein the connection member is a cylindrical member having a diameter D of 3.5 to 5 mm, the connection member has a circular surface that touches the embedded electrode, a cylinder side surface, and a corner portion between the circular surface and the cylinder side surface, the corner portion has a curvature radius R of 0.3 to 1.5 mm, and a ratio R/D is greater than or equal to 0.09.

This joined structure is capable of reducing the risk of breakage of the ceramic member while the joint strength is increased further than that in an existing structure. Specifically, in contrast to an existing connection member having a diameter D of approximately 3 mm, the structure according to the present invention has a diameter D of 3.5 to 5 mm. Thus, the structure according to the present invention has a larger joined area between the connection member and the externally conducting member and has larger joint strength. When the diameter D is increased, however, cracks are more likely to develop in the ceramic member from a corner portion between a surface of the connection member touching the embedded electrode and the cylinder side surface. Such development of cracks, however, can be avoided since the corner portion has a curvature radius R of 0.3 to 1.5 mm and the ratio R/D is determined to be greater than or equal to 0.09. Thus, the risk of breakage of the ceramic member can be reduced to a small level. Although the ratio R/D may be greater than 0.3, the crack preventive effect is not enhanced further in accordance with the increase and, instead, the contact area between the connection member and the embedded electrode decreases. Thus, the ratio R/D is preferably smaller than or equal to 0.3.

A second joined structure of the present invention comprises:

a ceramic member including a wafer-placement surface;

an embedded electrode embedded in the ceramic member and having a shape along a shape of the wafer-placement surface;

a connection member made of a metal and embedded in a surface of the ceramic member opposite to the wafer-placement surface so as to reach the embedded electrode; and

an externally conducting member made of a metal and joined to a surface of the connection member exposed to an outside with a joining layer interposed therebetween,

wherein the connection member is a cylindrical member having a diameter D of 3.5 to 5 mm, the connection member has a circular surface that touches the embedded electrode, a cylinder side surface, and a corner portion between the circular surface and the cylinder side surface, the corner portion has a shape of an ellipse having a minor axis F and a major axis G, the minor axis F and the major axis G are within a range of 0.3 to 1.5 mm, and a ratio F/D and a ratio G/D are greater than or equal to 0.09.

This joined structure is capable of reducing the risk of breakage of the ceramic member while the joint strength is increased compared to that in an existing structure. Specifically, in contrast to an existing connection member having a diameter D of approximately 3 mm, the structure according to the present invention has a diameter D of 3.5 to 5 mm. Thus, the structure according to the present invention has a larger joined area between the connection member and the externally conducting member and has larger joint strength. When the diameter D is increased, cracks are more likely to develop in the ceramic member from a corner portion between a surface of the connection member touching the embedded electrode and the cylinder side surface. Such development of cracks, however, can be prevented since the corner portion has a shape of an ellipse having a minor axis F and a major axis G, the minor axis F and the major axis G are within a range of 0.3 to 1.5 mm, and the ratio F/D and the ratio G/D are greater than or equal to 0.09. Thus, the risk of breakage of the ceramic member can be reduced to a small level. Although the ratio F/D and the ratio G/D may be greater than 0.3, the crack preventive effect is not enhanced further in accordance with the increase and, instead, the contact area between the connection member and the embedded electrode decreases. Thus, the ratio F/D and the ratio G/D are preferably smaller than or equal to 0.3.

In the joined structure according to the invention, a material of the ceramic member is preferably aluminium nitride, aluminium oxide, silicon carbide, or silicon nitride and a material of the connection member is preferably Mo, W, Nb, a Mo compound, a W compound, or a Nb compound. In this configuration, the difference between the coefficient of thermal expansion of the ceramic member and the coefficient of thermal expansion of the connection member is slight. Thus, thermal stress can be reduced to a small level, so that development of cracks in the ceramic member can be surely avoided. If, for example, the material of the ceramic member is AlN, the material of the connection member is preferably Mo. If the material of the ceramic member is Al₂O₃, the material of the connection member is preferably Nb or WC. If the material of the ceramic member is SiC, the material of the connection member is preferably WC. If the material of the ceramic member is Si₃N₄, the material of the connection member is preferably W or WC.

In the joined structure according to the present invention, a material of the joining layer is preferably Au, Al, Ag, a Au alloy, an Al alloy, or a Ag alloy. Thus, the joining layer can have higher strength. Using Au or a Au alloy as the material is more preferable since the resistance to oxidation can be enhanced in addition to the above-described effects.

In the joined structure according to the present invention, the externally conducting member may include a first section, joined to the connection member with a joining layer interposed therebetween, and a second section, joined to a surface of the first section opposite to the surface joined to the connection member with an intermediate joined portion interposed therebetween. The first section may be made of a metal having a lower coefficient of thermal expansion and higher resistance to oxidation than the second section. The first section may be surrounded by a guide member made of a metal having higher resistance to oxidation than the first section so as to be prevented from coming into direct contact with an ambient atmosphere.

### BRIEF DESCRIPTION OF THE DRAWINGS

FIG. 1 is a sectional view of a main portion of a ceramic heater 10.

FIGS. 2A to 2D are diagrams of a process of manufacturing the ceramic heater 10.

FIG. 3 is a sectional view of a main portion according to another embodiment.

FIG. 4 is a sectional view of a portion around a connection member 16 according to another embodiment.

FIG. 5 is a sectional view of a main portion of an existing ceramic heater 210.

### DETAILED DESCRIPTION OF THE INVENTION

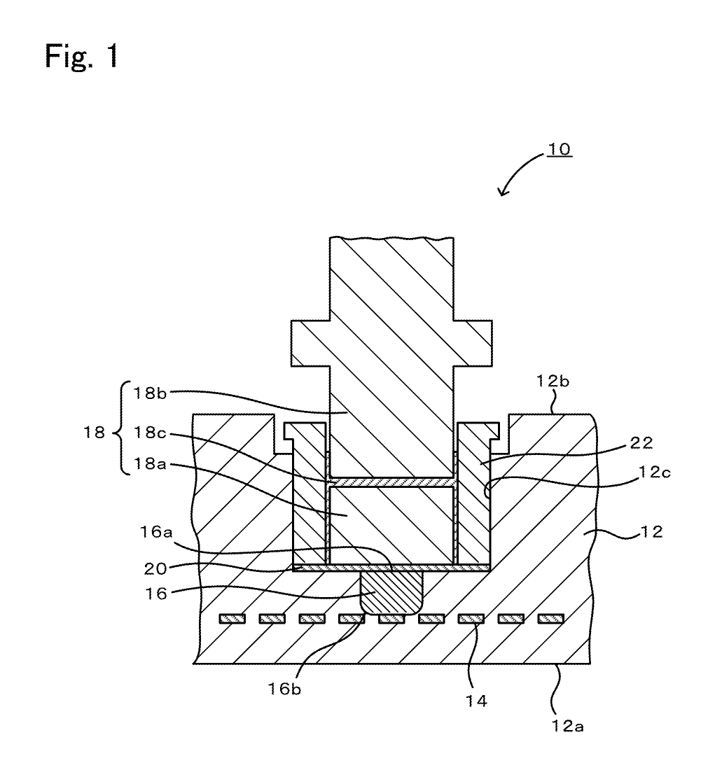

Now, a ceramic heater 10, which is a preferred embodiment of a joined structure of the present invention, is described below. FIG. 1 is a sectional view of a main portion of a ceramic heater 10.

The ceramic heater 10 is used for heating a wafer that is to be subjected to treatments such as etching or chemical vapor deposition (CVD), and disposed in a vacuum chamber, not illustrated. The ceramic heater 10 includes a ceramic member 12, a heater element (equivalent to an embedded electrode of the present invention) 14, a connection member 16, an externally conducting member 18, and a guide member 22.

The ceramic member 12 has a disk shape and has one surface serving as a wafer-placement surface 12a, on which a wafer is placed. In FIG. 1, the wafer-placement surface 12a faces down. When the ceramic heater 10 is actually used, however, the wafer-placement surface 12a is placed so as to face up. Examples preferably usable as the material of the ceramic member 12 include aluminium nitride, aluminium oxide, silicon carbide, and silicon nitride. A cylindrical closed-end hole 12c is formed in a surface 12b of the ceramic member 12, opposite to the wafer-placement surface 12a. The ceramic member 12 may have, for example, a diameter of 150 to 500 mm and a thickness of 0.5 to 30 mm. The hole 12c may have, for example, a diameter of 5 to 15 mm and a depth of 5 to 25 mm.

The heater element 14 is an electrode embedded in the ceramic member 12. The heater element 14 is a member having a shape along the shape of the wafer-placement surface 12a, here, a disk-shaped metal mesh. Examples preferably usable as the material of the heater element 14 include tungsten, molybdenum, tantalum, platinum, and alloys of these metals. The metal mesh may have, for example, lines of a line diameter of 0.1 to 1.0 mm at a density of 10 to 100 lines per inch.

The connection member 16 is a cylindrical metal member embedded in the bottom surface of the hole 12c of the ceramic member 12 so as to reach the heater element 14. The connection member 16 may be made of a bulk metal or a material obtained by sintering metal powder. Examples of usable metals include, besides molybdenum, tungsten, and niobium, a molybdenum compound such as molybdenum carbide, a tungsten compound such as tungsten carbide, and a niobium compound such as niobium carbide. An exposure surface 16a of the connection member 16, which is exposed from the bottom surface of the hole 12c, is flush with the bottom surface of the hole 12c. The connection member 16 has a diameter D of 3.5 to 5 mm. The connection member 16 includes a corner portion 16b between a circular surface touching the heater element 14 and a cylinder side surface. The corner portion 16b has a curvature radius R of 0.3 to 1.5 mm. The ratio R/D is within a range of 0.09 to 0.30. The connection member 16 may have a height of, for example, 1 to 5 mm.

The externally conducting member 18 includes a first section 18a, joined to the connection member 16 with a joining layer 20 interposed therebetween, and a second section 18b, joined to a surface of the first section 18a opposite to the joined surface joined to the connection member 16, with an intermediate joined portion 18c interposed therebetween. The second section 18b is made of a metal having high resistance to oxidation to allow for use in a plasma atmosphere or a corrosive gas atmosphere. Typical metals having high resistance to oxidation, however, have a high coefficient of thermal expansion. Thus, when such metals are directly joined to the ceramic member 12, the joint strength is reduced by a difference in thermal expansion between these materials. Thus, the second section 18b is joined to the ceramic member 12 with the first section 18a interposed therebetween, the first section 18a being made of metals having a coefficient of thermal expansion closer to the coefficient of thermal expansion of the connection member 16. Such metals usually have insufficient resistance to oxidation. Thus, the first section 18a is surrounded by the guide member 22 made of metals having high resistance to oxidation so as to avoid direct contact with a plasma atmosphere or corrosive gas atmosphere. Examples preferably usable as the material of the second section 18b include pure nickel, a nickel-base heat-resistant alloy, gold, platinum, silver, and alloys of these metals. Examples preferably usable as the material of the first section 18a includes molybdenum, tungsten, a molybdenum-tungsten alloy, a tungsten-copper-nickel alloy, and Kovar. The joining layer 20 is joined by brazing. Preferably usable as the brazing is metal brazing. For example, Au—Ni brazing, Al brazing, or Ag brazing is preferable. The joining layer 20 joins the bottom surface of the hole 12c, including the exposure surface 16a of the connection member 16, and the end surface of the first section 18a to each other. The intermediate joined portion 18c of the externally conducting member 18 joins the first section 18a and the second section 18b to each other. In addition, a gap between the inner peripheral surface of the guide member 22 and the entirety or part of the outer peripheral surface of the first section 18a or a gap between the inner peripheral surface of the guide member 22 and part of the outer peripheral surface of the second section 18b is filled with the intermediate joined portion 18c. Thus, the first section 18a is insulated against contact with an ambient atmosphere by the intermediate joined portion 18c. Materials the same as those for the joining layer 20 are usable for the intermediate joined portion 18c. The first section 18a may have a diameter of 3 to 6 mm and a height of 2 to 5 mm. The second section 18b may have a diameter of 3 to 6 mm and any height.

The guide member 22 is a cylindrical tube member surrounding a portion of the externally conducting member 18, the portion including at least the first section 18a. The guide member 22 is made of a material having higher resistance to oxidation than the first section 18a. The guide member 22 has an inner diameter larger than the outer diameter of the first section 18a and the second section 18b (excluding the flange), an outer diameter smaller than the diameter of the hole 12c, and a height larger than the height of the first section 18a. The end surface of the guide member 22 facing the bottom surface of the hole 12c is joined to the connection member 16, the externally conducting member 18, and the ceramic member 12 with the joining layer 20 interposed therebetween. Examples usable as the material of the guide member 22 are the same as those exemplified as the materials for the second section 18b of the externally conducting member 18.

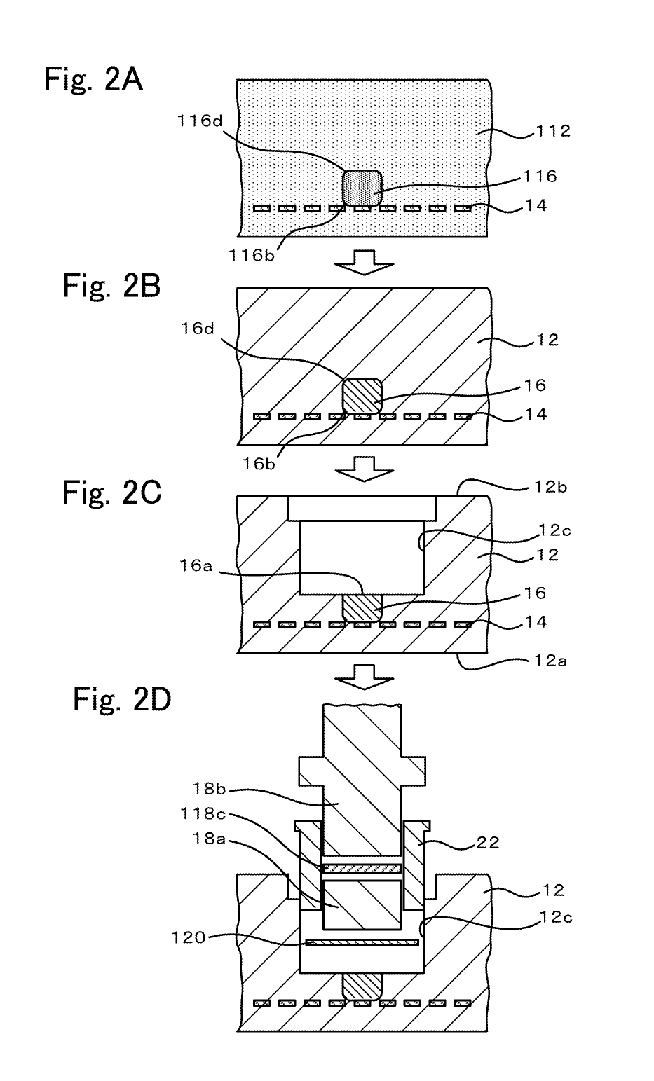

Referring now to the manufacturing process in FIGS. 2A to 2D, a method for manufacturing the ceramic heater 10 is described below. First, a compact 112 is formed by pressing ceramic material powder into a circular plate (see FIG. 2A). A heater element 14, made of a circular metal mesh, and a metal powder cylindrical body 116, serving as the connection member 16, are embedded in advance in the compact 112. The cylindrical body 116 is formed in such a manner that a corner portion 116b at the circular surface touching the heater element 14 or a corner portion 116d at the circular surface opposite to the circular surface touching the heater element 14 has a predetermined curvature radius. When the compact 112 is fired in, for example, a hot-press furnace or a normal-pressure furnace, the cylindrical body 116 is sintered and changed into a connection member 16 and the compact 112 is sintered and changed into a ceramic member 12 (see FIG. 2B). During firing, cracks do not develop from the corner portions 116b and 116d of the cylindrical body 116 since the corner portions 116b and 116d are rounded. Each of corner portions 16b and 16d between the corresponding one of the upper and lower circular surfaces and the cylinder side surface of the connection member 16 has a curvature radius R. The obtained ceramic member 12 is machined so as to have a predetermined size.

Subsequently, a cylindrical closed-end hole 12c is formed by grinding a surface 12b of the ceramic member 12 opposite to the wafer-placement surface 12a (see FIG. 2C). At this time, the cylindrical closed-end hole 12c is formed in such a manner that the bottom surface of the hole 12c is flush with the exposure surface 16a of the connection member 16. Thus, the corner portion 16d of the connection member 16 is removed.

Subsequently, a brazing member 120 serving as a joining layer 20 is spread over the bottom surface of the hole 12c. On the brazing member 120, the first section 18a of the externally conducting member 18, a brazing member 118c, serving as the intermediate joined portion 18c, the guide member 22, and the second section 18b of the externally conducting member 18 are stacked one on top of another in this order to form a multilayer body (see FIG. 2D). The multilayer body is heated under nonoxidative conditions to melt the brazing members 118c and 120 and left until solidified. Thus, the ceramic heater 10 illustrated in FIG. 1 is obtained. The nonoxidative conditions represent a vacuum or nonoxidative atmosphere (for example, an inert atmosphere such as an argon atmosphere or a nitrogen atmosphere).

The ceramic heater 10 according to the embodiment thus described is capable of reducing the risk of breakage of the ceramic member 12 while the joint strength is enhanced compared to an existing structure. Specifically, in contrast to the existing connection member 216 having a diameter D of approximately 3 mm, the ceramic heater 10 according to the embodiment has a diameter D of 3.5 to 5 mm. Thus, the joined area between the connection member 16 and the externally conducting member 18 increases and the joint strength increases. The increase of the diameter D, on the other hand, encourages development of cracks from the corner portion 16b of the connection member 16 toward the ceramic member 12. Such development of cracks, however, can be avoided since the corner portion 16b has a curvature radius R of 0.3 to 1.5 mm and the ratio R/D is set to be greater than or equal to 0.09. Thus, the risk of breakage of the ceramic member can be reduced. Here, the ratio R/D may be higher than 0.3. Nevertheless, this is not preferable because the crack prevention effect does not increase further in accordance with the increase and, instead, the contact area between the connection member 16 and the heater element 14 decreases.

The material of the ceramic member 12 is any of aluminium nitride, aluminium oxide, silicon carbide, and silicon nitride and the material of the connection member 16 is any of Mo, W, Nb, a Mo compound, a W compound, and a Nb compound. Thus, the difference between the coefficient of thermal expansion of the ceramic member 12 and the coefficient of thermal expansion of the connection member 16 is slight, so that the thermal stress can be reduced to a small level. Thus, development of cracks in the ceramic member 12 can be surely avoided.

Moreover, the material of the joining layer 20 is any of Au—Ni brazing, Al brazing, and Ag brazing. Thus, the strength of the joining layer 20 can be enhanced.

The present invention is not limited to the above-described embodiment, and can be carried out by various modes as long as they belong to the technical scope of the invention.

In the above-described embodiment, the ceramic heater 10 is described as an example of the joined structure of the present invention. However, the joined structure may be an electrostatic chuck or a component of a high-frequency electrode. In the case where the joined structure is an electrostatic chuck, an electrostatic electrode is suitable for being embedded instead of the heater element 14. In the case where the joined structure is a component of a high-frequency electrode, a high-frequency electrode is suitable for being embedded instead of the heater element 14.

In the above-described embodiment, a disk-shaped metal mesh is used as the heater element 14 but a disk-shaped metal sheet or a coil spring may be used, instead. When a coil spring is used, for example, a one end of the coil spring may be placed at the center of the ceramic member 12, and the coil spring may be wired over the entire area in a unicursal manner from the one end, and the other end may then be placed near the one end.

A tubular shaft made of the same material as the ceramic member 12 may be disposed on the surface 12b of the ceramic heater 10 according to the above-described embodiment, opposite to the wafer-placement surface 12a, and integrated with the ceramic member 12. In this case, the externally conducting member 18 and other components are disposed inside the hollow space of the shaft. A suitable way for manufacturing such a shaft is, for example, to shape ceramic material powder by cold isostatic press (CIP) using a die set, fire the ceramic material powder at a predetermined temperature in a normal-pressure furnace, and after firing, machines the resultant ceramic material to have a predetermined size. A suitable way for integrating the shaft and the ceramic member 12 together is, for example, to butt the end surface of the shaft against the surface 12b of the ceramic member 12, raise the temperature to a predetermined temperature, and join the shaft and the ceramic member 12 together until they are integrated.

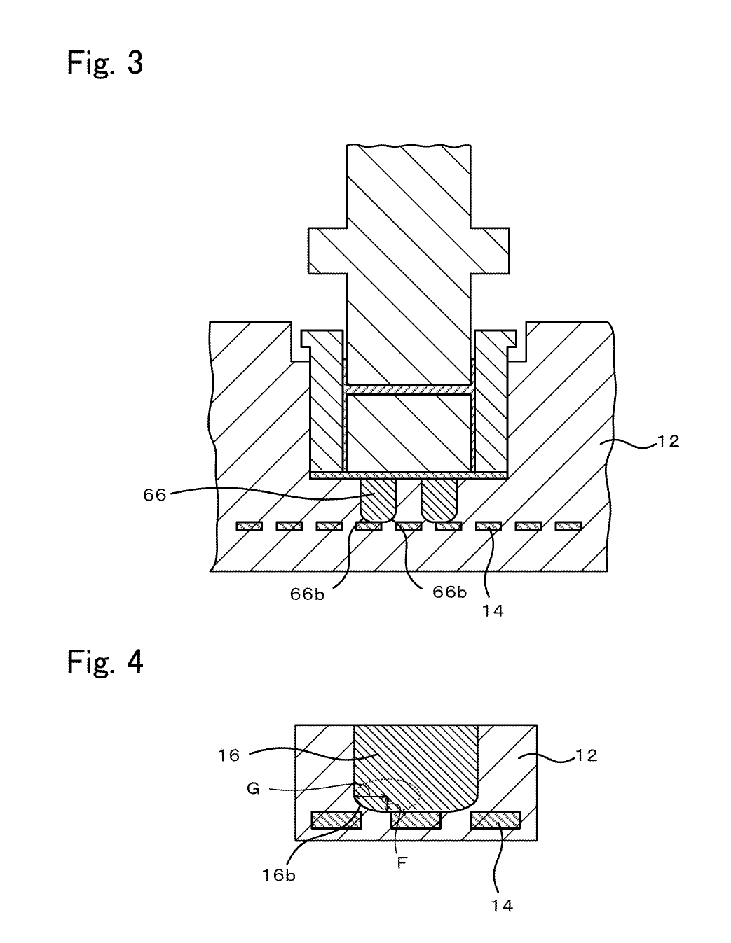

In the above-described embodiment, the connection member 16 is a solid cylinder member. However, as illustrated in FIG. 3, the connection member 16 may be a cylindrical member (ring-shaped member) 66 having a through hole along the axis. The ring-shaped member 66 has a diameter (outer diameter) D of 3.5 to 5 mm. The ring-shaped member 66 has corner portions 66b at the surface touching the heater element 14. The corner portions 66b have a curvature radius R of 0.3 to 1.5 mm. The ratio R/D is set to be within 0.09 to 0.30. This configuration has the same effects as in the case of the above-described embodiment. The outer diameter or the inner diameter of the ring-shaped member 66 is preferably determined in such a manner that the joined area between the ring-shaped member 66 and the externally conducting member 18 (area in the ring-shaped portion) is larger than the existing joined area between the connection member 216 and the externally conducting member 218.

In the ceramic heater 10 according to the above-described embodiment, the wafer-placement surface 12a may be flat. Instead, the wafer-placement surface 12a may be embossed, or processed so as to have a pocket or groove.

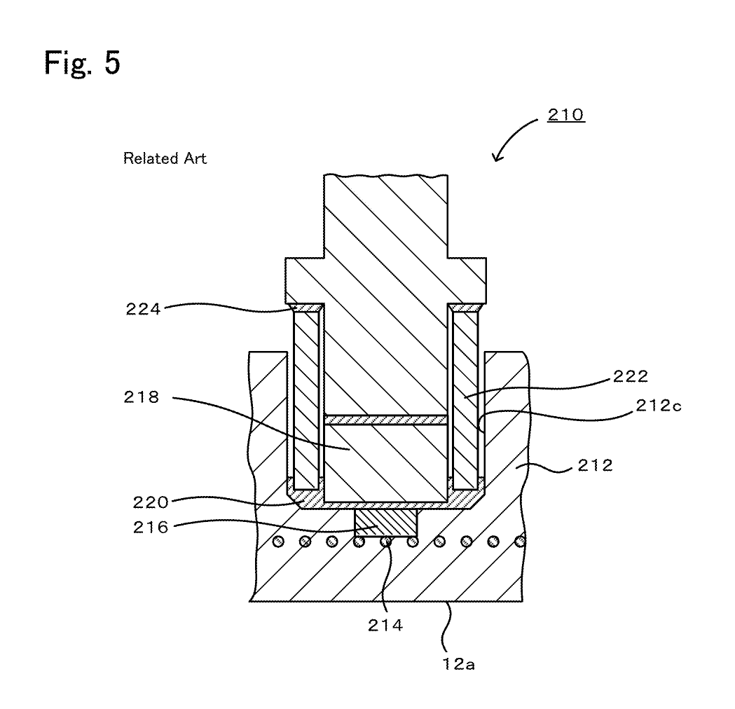

In the above-described embodiment, the flange of the second section 18b of the externally conducting electrode member 18 and the end surface of the guide member 22 are not joined together. However, as in the existing case illustrated in FIG. 5, the flange of the second section 18b of the externally conducting electrode member 18 and the end surface of the guide member 22 may be closed up and a gap between these members may be filled with a joining layer (for example, made of the same material as the material of the joining layer 20) to join these members with the joining layer interposed therebetween.

In the above-described embodiment, the corner portion 16b of the connection member 16 has a curvature radius R of 0.3 to 1.5 mm and the ratio R/D is greater than or equal to 0.09. However, as illustrated in FIG. 4, the corner portion 16b may have a shape of an ellipse having a minor axis F and a major axis G, where the ratio F/D and the ratio G/D are greater than or equal to 0.09 (preferably 0.09 to 0.3). This configuration also has the same effects as in the case of the above-described embodiment. In FIG. 4, the minor axis F extends in the direction of the height of the connection member 16 (vertical direction in FIG. 4) and the major axis G extends in the direction of the width of the connection member 16 (lateral direction in FIG. 4). However, the minor axis F may extend in the width direction and the major axis G may extend in the height direction.

### Examples

Examples of the present invention are described below. The examples described below do not limit the present invention.

### Test Examples 1 to 9

In accordance with the manufacturing process in FIGS. 2A to 2D, nine kinds of samples of the above-described ceramic heater 10 were manufactured (test examples 1 to 9). First, a heater element 14 and a cylindrical body 116 were embedded in aluminium nitride powder and the powder was uniaxially pressed to form a compact 112. A molybdenum wire net was used as the heater element 14. The wire net was obtained by weaving molybdenum wires having a diameter of 0.12 mm at a density of 50 lines per inch. An example used as the cylindrical body 116 was obtained from forming molybdenum powder having a particle diameter of 1 to 100 μm into a cylinder shape and processing the cylinder powder compact so that the corner portion 116b between the circular surface touching the heater element 14 and the cylinder side surface has a predetermined curvature radius R. This compact 112 was placed in a die set, sealed in a carbon foil, and fired by hot press to obtain the ceramic member 12. Firing was performed while a temperature was kept at 1950° C. and a pressure was kept at 200 kgf/cm² for two hours. The ceramic member 12 was then processed to have a diameter of 200 mm and a thickness of 8 mm.

Subsequently, the cylindrical closed-end hole 12c was formed in the surface 12b of the ceramic member 12 opposite to the wafer-placement surface 12a by a machining center. The hole 12c had a diameter of 9 mm (opening diameter of 12 mm) and a depth of 4.5 mm. At this time, the cylindrical closed-end hole 12c was formed in such a manner that the bottom surface of the hole 12c and the exposure surface 16a of the connection member 16 are flush with each other.

Subsequently, a brazing member 120 made of Au—Ni was spread over the bottom surface of the hole 12c. On the brazing member 120, a first section 18a of the externally conducting member 18, a brazing member 118c made of Au—Ni, a guide member 22 made of nickel (with a purity greater than or equal to 99%), and the second section 18b of the externally conducting member 18 were stacked one on top of another in this order to obtain a multilayer body. A component made of Kovar and having a diameter of 4 mm and a height of 3 mm was used as the first section 18a. A component made of nickel (with a purity greater than or equal to 99%) and having a diameter of 4 mm (flange diameter of 8 mm) and a height of 60 mm was used as the second section 18b. This multilayer body was heated in an inert atmosphere for ten minutes at 960 to 1000° C. to obtain the ceramic heater 10 illustrated in FIG. 1.

Table 1 shows the diameter D of the connection member 16, the curvature radius R of the corner portion, and the ratio R/D of each of the test examples 1 to 9. The height of the connection member 16 is fixed at 3 mm throughout the examples. The following evaluation test was performed on each of the test examples 1 to 9. The results are shown in Table 1.

(Measurement of Tensile Break Strength)

At room temperature, the ceramic member 12 was fixed in position, the flange of the externally conducting member 18 was held and vertically pulled up to measure the load at the time when the joint between the connection member 16 and the externally conducting member 18 was broken. The load was determined as the tensile break strength. A tensile strength tester (Autograph from Shimadzu Corporation) was used for measurement.

(Breakage Occurred or Not During Manufacture)

Whether any crack developed in each ceramic member 12 immediately after the ceramic member 12 had been manufactured by sintering the compact 112 was checked and the one in which a crack had developed was determined as being broken during manufacture.

(Ceramic Breakage Occurred or Not)

Under vacuum, the ceramic heater 10 was heated to 700° C. and then cooled down to room temperature. In this state, whether any crack developed in each ceramic member 12 was checked and the one in which a crack had developed was determined as having ceramic breakage. Here, thermal stress results from a slight difference between the coefficient of thermal expansion of the material (AlN) of the ceramic member 12 and the coefficient of thermal expansion of the material (Mo) of the connection member 16. The thermal stress is more likely to concentrate on the corner portion 16b, so that cracks from the corner portion 16b are more likely to develop in the ceramic member 12.

TABLE 1

| | Size of connection electrode member | | | Evaluation result | | |
|---|---|---|---|---|---|---|
| | | Curvature radius | | Tensile | | |
| | | R of corner | | break | Breakage | |
| Test | Diameter D | portion | | strength | during | Ceramic |
| example | (mm) | (mm) | R/D | (kgf) | manufacture | breakage |
| 1 | 3.0 | 0.2 | 0.07 | 124 | Not occurred | Not occurred |
| 2 | 3.5 | 0.2 | 0.06 | 166 | Not occurred | Occurred |
| 3 | 4.0 | 0.2 | 0.05 | — | Occurred | — |
| 4 | 3.5 | 0.3 | 0.09 | 169 | Not occurred | Not occurred |
| 5 | 3.5 | 0.5 | 0.14 | 158 | Not occurred | Not occurred |
| 6 | 4.0 | 0.5 | 0.13 | 207 | Not occurred | Not occurred |
| 7 | 4.5 | 1.0 | 0.22 | 256 | Not occurred | Not occurred |
| 8 | 5.0 | 1.5 | 0.30 | 294 | Not occurred | Not occurred |
| 9 | 5.5 | 1.5 | 0.27 | — | Occurred | — |

The test examples 1 to 3 are compared with one another. Throughout the test examples 1 to 3, the corner portions 16b have a curvature radius R of 0.2 mm. The test example 1 had a smaller diameter D than the test examples 2 and 3. Thus, the thermal stress concentrated on the corner portion 16b of the test example 1 was small, so that neither breakage during manufacture nor ceramic breakage was observed. The ratio R/D here was 0.07. In contrast, ceramic breakage was observed in the test example 2, since the test example 2 had a larger diameter D than the test example 1 and the thermal stress was larger. In the test example 3, breakage during manufacture was observed since the test example 3 had a larger diameter D than the test examples 1 and 2 and the thermal stress was much larger. The test examples 2 and 3 respectively had a ratio R/D of 0.06 and a ratio R/D of 0.05. On the other hand, the test example 1 had lower tensile break strength than the test examples 2 and 3 since the test example 1 had a smaller diameter D.

The test examples 4 to 8 had diameters D of 3.5 to 5.0 mm, which are larger than the diameter D of the test example 1, so that the thermal stress concentrated on each corner portion 16b was larger. However, since each corner portion 16b had a curvature radius R of 0.3 to 1.5 mm and each test example had a ratio R/D of 0.09 to 0.30, breakage during manufacture and ceramic breakage could be avoided. The joined area between the connection member 16 and the externally conducting member 18 in each of the test examples 4 to 8 was much larger than that in the test example 1. This increase in the joined area enhanced the tensile break strength of each of the test examples 4 to 8 compared to that of the test example 1.

The test example 9 had a diameter D of as large as 5.5 mm. Thus, the thermal stress concentrated on the corner portion 16b was quite large, so that development of a crack resulting from the thermal stress during manufacture failed to be avoided although the curvature radius R of the corner portion 16b was 1.5 mm and the ratio R/D was 0.27.

Among the test examples 1 to 9, the test examples 4 to 8 correspond to the examples of the present invention and the others correspond to comparative examples.

### Test Examples 10 to 13

The ceramic heater 10 in each of the test examples 10 to 13 was manufactured in the same manner as that in the case of the test examples 1 to 9 except that the cylindrical body 116 had a corner portion 116b formed in an elliptic shape, the corner portion 116b being located between the circular surface touching the heater element 14 and the cylinder side surface. Table 2 shows the diameter D of the connection member 16, the minor axis F and the major axis G of the ellipse at the corner portion, the ratio F/D, and the ratio G/D of the test examples 10 to 13. The connection members 16 of all the test examples had a height of 3 mm. The direction of the minor axis of the ellipse corresponds to the direction of the height of each connection member 16 (vertical direction in FIG. 4). The direction of the major axis of the ellipse corresponds to the direction of the width of each connection member 16 (lateral direction in FIG. 4). Each evaluation test was performed on the test examples 10 to 13. The results are shown in Table 2.

TABLE 2

| | Size of connection electrode member | | | | | | | | |
|---|---|---|---|---|---|---|---|---|---|
| | | | | | | Ratio of | Evaluation result | | |
| | | Minor axis F | | Major axis G | | minor axis | Tensile | | |
| | Diameter | of ellipse of | | of ellipse of | | to major | strength | Breakage | |
| Test | D | corner | | corner | | axix | break | during | Ceramic |
| example | (mm) | portion(mm) | F/D | portion(mm) | G/D | F/G | (kgf) | manufacture | breakage |
| 10 | 3.5 | 0.3 | 0.09 | 0.5 | 0.14 | 0.60 | 156 | Not occurred | Not occurred |
| 11 | 3.5 | 0.2 | 0.06 | 0.8 | 0.23 | 0.25 | 164 | Not occurred | Occurred |
| 12 | 5.0 | 0.5 | 0.10 | 0.8 | 0.16 | 0.63 | 285 | Not occurred | Not occurred |
| 13 | 5.0 | 0.2 | 0.04 | 1.2 | 0.24 | 0.17 | — | Occurred | — |

The test examples 10 and 12 had diameters D of 3.5 to 5.0 mm, so that the thermal stress concentrated on each corner portion 16b was large. However, occurrences of breakage during manufacture and ceramic breakage were prevented as a result of appropriately determining the minor axis F and the major axis G of the ellipse of each corner portion 16b, the ratio F/D, and the ratio G/D. The test examples 11 and 13, in contrast, were broken during manufacture or while being cooled down after being heated since either one of these values was not appropriately determined.

Among the test examples 10 to 13, the test examples 10 and 12 correspond to examples of the present invention and the others correspond to comparative examples.

The present application claims priority from Japanese Patent Application No. 2014-132305 filed on Jun. 27, 2014, the entire contents of which are incorporated herein by reference.

Naturally, the examples described above never limit the present invention.

What is claimed is:

1. A joined structure comprising:
a ceramic member including a wafer-placement surface;
an embedded electrode embedded in the ceramic member and having a shape along a shape of the wafer-placement surface;
a connection member made of a metal and embedded in a surface of the ceramic member opposite to the wafer-placement surface so as to reach the embedded electrode; and
an externally conducting member made of a metal and joined to a surface of the connection member exposed to an outside with a joined layer interposed therebetween,
wherein the connection member is a cylindrical member having a diameter D of 3.5 to 5 mm, the connection member has a circular surface that touches the embedded electrode, a cylinder side surface, and a corner portion between the circular surface and the cylinder side surface, the corner portion has a curvature radius R of 0.3 to 1.5 mm, and a ratio R/D is greater than or equal to 0.09.

2. The joined structure according to claim 1, wherein the ratio R/D is smaller than or equal to 0.3.

3. A joined structure comprising:
a ceramic member including a wafer-placement surface;
an embedded electrode embedded in the ceramic member and having a shape along a shape of the wafer-placement surface;
a connection member made of a metal and embedded in a surface of the ceramic member opposite to the wafer-placement surface so as to reach the embedded electrode; and
an externally conducting member made of a metal and joined to a surface of the connection member exposed to an outside with a joined layer interposed therebetween,
wherein the connection member is a cylindrical member having a diameter D of 3.5 to 5 mm, the connection member has a circular surface that touches the embedded electrode, a cylinder side surface, and a corner portion between the circular surface and the cylinder side surface, the corner portion has a shape of an ellipse having a minor axis F and a major axis G, the minor axis F and the major axis G are within a range of 0.3 to 1.5 mm, and a ratio F/D and a ratio G/D are greater than or equal to 0.09.

4. The joined structure according to claim 3,
wherein the ratio F/D and the ratio G/D are smaller than or equal to 0.3.

5. The joined structure according to claim 1,
wherein a material of the ceramic member is aluminium nitride, aluminium oxide, silicon carbide, or silicon nitride and a material of the connection member is Mo, W, Nb, a Mo compound, a W compound, or a Nb compound.

6. The joined structure according to claim 3,
wherein a material of the ceramic member is aluminium nitride, aluminium oxide, silicon carbide, or silicon nitride and a material of the connection member is Mo, W, Nb, a Mo compound, a W compound, or a Nb compound.

7. The joined structure according to claim 1,
wherein a material of the joined layer is Au or a Au alloy.

8. The joined structure according to claim 3,
wherein a material of the joined layer is Au or a Au alloy.
